(19) United States
(12) Patent Application Publication
(10) Pub. No.: US 2024/0088624 A1
(43) Pub. Date: Mar. 14, 2024

(54) MULTI-ACTIVE-REGION CASCADED BRAGG REFLECTION WAVEGUIDE EDGE-EMITTING DIODE LASER

(71) Applicant: Jlight Semiconductor Technology Co., Ltd., Changchun (CN)

(72) Inventors: Lijie WANG, Changchun (CN); Cunzhu TONG, Changchun (CN); Hangyu PENG, Changchun (CN); Lijun WANG, Changchun (CN)

(21) Appl. No.: 18/510,182

(22) Filed: Nov. 15, 2023

(30) Foreign Application Priority Data
Dec. 20, 2022 (CN) 202211635849.7

(51) Int. Cl. H01S 5/125; H01S 5/34

(52) U.S. Cl. CPC H01S 5/125; H01S 5/3416

(57) ABSTRACT

A multi-active region cascaded Bragg reflection waveguide edge-emitting diode laser, including a substrate, a buffer layer, an N-type cladding layer, an N-type waveguide layer, a cascaded multi-active region, a P-type waveguide layer, a P-type cladding layer and a capping layer arranged sequentially from bottom to top. The waveguide layer adopts a Bragg reflection waveguide structure formed by periodic arrangement of high and low refractive index layers. The cascaded multi-active region includes multiple active regions, tunnel junctions and a confinement layer. A fundamental mode near field of the laser is formed by periodic oscillating peaks, with an envelope close to Gaussian distribution. There are large-swing oscillation peaks near the cascaded multi-active region. The active regions are located at peaks of the fundamental mode near field, and tunnel junctions are inserted at troughs with low light intensity.

### CROSS-REFERENCE TO RELATED APPLICATIONS

This application claims the benefit of priority from Chinese Patent Application No. 202211635849.7, filed on Dec. 20, 2022. The content of the aforementioned application, including any amendments made thereto, is incorporated herein by reference in its entirety.

### TECHNICAL FIELD

This application relates to diode lasers, and more particularly to a multi-active-region cascaded Bragg reflection waveguide edge-emitting diode laser.

### BACKGROUND

Lidar has been extensively used in three-dimensional sensing, surveying and mapping, cockpit monitoring, assisted driving, and robot or drone navigation. Diode lasers are considered as a preferred signal emission light source in lidar technology. In order to improve the detection range, ranging accuracy and anti-interference ability of the lidar system, diode laser chips with high pulse power, low beam divergence angle and stable wavelength are needed.

In order to achieve the high pulse power laser output, a multi-junction diode laser structure can be adopted, in which multiple active regions are cascaded using n⁺/p⁺ tunnel junctions in the epitaxial growth. At present, the commercially-available devices usually adopt a non-coupled multi-junction laser structure, in which individual light-emitting regions have an independent waveguide layer and a cladding layer, and a light intensity near the tunnel junctions is zero, thereby reducing the loss. However, the vertical beam size of this laser increases by several times, and the beam divergence angle is still very large (usually greater than 30° like a single junction emitter), resulting in poor vertical beam quality. Therefore, it is not conducive to beam shaping and limits the resolution of lidar detection.

In addition, lidar systems usually adopt narrow-band filters to suppress background light, but this requires output lasers to be kept within a narrow spectral range over a wide temperature range, which can be achieved through monolithic integration of a Bragg grating. However, for traditional uncoupled multi-junction lasers, individual emitting regions work independently, and a buried grating or surface grating only affects adjacent emitting points or the top emitting points, without effecting on other emitting points. However, the multiple buried grating preparations and epitaxial growths result in complex process and high cost, making it difficult for practical application.

To solve the problems mentioned above, it has been proposed to epitaxially stack several active regions alternating with tunnel junctions in a single waveguide, instead of stacking independently-operating laser diodes. Traditional diode lasers adopt a total reflection waveguide in the vertical direction, and a distance between adjacent two light-emitting regions is too small such that waveguide layers of the two light-emitting regions will be coupled into an expansion layer of the same mode. This causes an intense optical near-field to overlap with highly-doped tunnel junctions, resulting in large carrier absorption loss and reduced laser power and efficiency. If the laser operates in a high-order mode, the active region and the tunnel junction can be located at the nodes and antinodes, respectively, but this will lead to a large far-field divergence angle, which is usually a multi-peak structure with poor beam quality, and is not conducive to lidar applications.

In summary, how to improve the pulse power and beam quality of diode lasers while being compatible with the built-in grating wavelength-locking technology has become a technical problem urgently needed to be solved by those skilled in the art.

### SUMMARY

An object of the disclosure is to provide a multi-active region cascaded Bragg reflection waveguide edge-emitting diode laser with enhanced power and beam quality to overcome the technical defects existing in the prior art.

Technical solutions of the present disclosure are described as follows.

This application provides a multi-active region cascaded Bragg reflection waveguide edge-emitting diode laser, comprising:
a substrate;
a buffer layer;
an N-type cladding layer;
an N-type waveguide layer;
a cascaded multi-active region;
a P-type waveguide layer;
a P-type cladding layer; and
a capping layer;
wherein the substrate, the buffer layer, the N-type cladding layer, the N-type waveguide layer, the cascaded multi-active region, the P-type waveguide layer, the P-type cladding layer and the capping layer are sequentially arranged from bottom to top; the N-type waveguide layer is a Bragg reflection waveguide formed by periodic and alternate growth of a plurality of first refractive index layers and a plurality of second refractive index layers, and the P-type waveguide layer is a Bragg reflection waveguide formed by periodic and alternate growth of a plurality of third refractive index layers and a plurality of fourth refractive index layers; a refractive index of the plurality of first refractive index layers is larger than that of the plurality of second refractive index layers; a refractive index of the plurality of third refractive index layers is larger than that of the plurality of fourth refractive index layers; the cascaded multi-active region comprises a plurality of active regions, a plurality of tunnel junctions and a confinement layer; the plurality of active regions and the plurality of tunnel junctions are located in the confinement layer; each of the plurality of tunnel junctions is located between two adjacent active regions of the plurality of active regions; the plurality of active regions are respectively located at peaks of a fundamental mode near field; the plurality of tunnel junctions are respectively located at troughs of the fundamental mode near field; and the plurality of active regions are configured to share the same waveguide.

In some embodiments, the confinement layer comprises:
a plurality of fifth refractive index layers; and
a plurality of sixth refractive index layers;
wherein a refractive index of the plurality of fifth refractive index layers is larger than that of the plurality of sixth refractive index layers; the plurality of fifth refractive index layers and the plurality of sixth refractive index layers are configured to grow alternately; the plurality of active regions are respectively inserted in the plurality of fifth refractive index layers; and the plurality of tunnel junctions are respectively inserted in the plurality of sixth refractive index layers.

In some embodiments, the plurality of fifth refractive index layers vary in composition and thickness; and the plurality of sixth refractive index layers vary in composition and thickness.

In some embodiments, the number k of the plurality of active regions is equal to or larger than 2; and the number of the plurality of tunnel junctions is k−1, wherein k is a natural number.

In some embodiments, the plurality of first refractive index layers are different from the plurality of third refractive index layers in composition and thickness; the plurality of second refractive index layers are different from the plurality of fourth refractive index layers in composition and thickness; and a period number of the plurality of third refractive index layers and the plurality of fourth refractive index layers is less than or equal to a period number of the plurality of first refractive index layers and the plurality of second refractive index layers.

In some embodiments, a refractive index of the P-type cladding layer is lower than a refractive index of the N-type cladding layer.

In some embodiments, each of the plurality of tunnel junctions comprises a first doped material and a second doped material; a conductivity type of the first doped material is opposite to that of the second doped material; and for each of the plurality of tunnel junctions, a conductivity type of a material between the first doped material and an adjacent active region thereof is different from that of a material between the second doped material and an adjacent active region thereof.

In some embodiments, the plurality of active regions are independently a single-layer or multi-layer quantum well, quantum dot or quantum wire.

In some embodiments, the substrate is GaAs, InP, GaSb or GaN.

In the multi-active region cascaded Bragg reflection waveguide edge-emitting diode laser provided herein, the material and thickness of individual layers in the Bragg reflection waveguide and the cascaded multi-active region are controlled to allow light to be transmitted in the high refractive index layers in the Bragg reflection waveguide but to be gradually attenuated in the low refractive index layers, thereby forming a periodic-oscillating Gaussian-like near-field distribution. An amplitude difference of oscillating peaks near the active regions is increased to allow the active region and the tunnel junction to be located at the peak and trough of the fundamental mode near field, respectively, which can effectively improve the optical confinement factor and reduce the absorption loss of the tunnel junctions, thereby generating a high-power, low-beam divergence laser output. In addition, since the multiple active regions share a single vertical waveguide mode, output wavelength locking and spectral narrowing of the multiple active regions can be achieved simultaneously through integrating a grating.

In the technical solutions of the disclosure disclosed above, a Bragg reflection waveguide structure is adopted to achieve a light field with Gaussian-like distribution with large-amplitude periodic oscillation. In this way, the multiple active regions can be introduced at peaks of a central light field, and the tunnel junctions can be introduced at troughs of a light field near the active regions, so as to reduce the light absorption loss and achieve high-power laser output. The laser also has characteristics of a large laser cavity and a strong mode selection, which can achieve stable single-mode operation with a large optical mode volume, effectively improving the cavity surface catastrophic damage power and beam quality. Meanwhile, a vertical divergence angle can be compressed from more than 30° of traditional devices to less than 10°, which is more conducive to device collimation and application. In addition, the multi-active regions of the laser share the same waveguide mode. Through buried growth or surface etching gratings, wavelength locking and spectral narrowing of the multi-active regions can be achieved simultaneously, making it feasible for lidar systems to use narrow-band filters to suppress background light noise, which is of great significance. In general, the laser can achieve laser output with high pulse power and low beam divergence, and has a promising application prospect.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

In order to explain the technical solutions in the embodiments of the present application or the technical solutions in the prior art more clearly, the accompanying drawings needed in the description of the embodiments or prior art will be briefly introduced below. Obviously, presented in the drawings are merely some embodiments of the present application, which are not intended to limit the present application. For those of ordinary skill in the art, other drawings can be obtained based on the provided drawings without exerting creative efforts.

FIG. 1 is a structural diagram of a multi-active region cascaded Bragg reflection waveguide edge-emitting diode laser according to an embodiment of the present disclosure;

FIG. 2 is a structural diagram of a cascaded multi-active region of the multi-active region cascaded Bragg reflection waveguide edge-emitting diode laser according to an embodiment of the present disclosure;

FIG. 3 schematically illustrates refractive index distribution in individual layers of the multi-active region cascaded Bragg reflection waveguide edge-emitting diode laser according to an embodiment of the present disclosure;

FIG. 4 schematically shows distribution of the cascaded multi-active region and a fundamental mode near field of the multi-active region cascaded Bragg reflection waveguide edge-emitting diode laser according to an embodiment of the present disclosure;

FIG. 5 schematically shows refractive index distribution and fundamental mode near-field intensity distribution of the multi-active region cascaded Bragg reflection waveguide edge-emitting diode laser according to Embodiment 1 of the present disclosure;

FIG. 6 schematically shows far-field intensity distribution of the multi-active region cascaded Bragg reflection waveguide edge-emitting diode laser according to Embodiment 1 of the present disclosure; and

FIG. 7 schematically depicts refractive index distribution and fundamental mode near-field intensity distribution of the multi-active region cascaded Bragg reflection waveguide edge-emitting diode laser according to Embodiment 2 of the present disclosure.

In the drawings:

1. substrate; 2. buffer layer; 3. N-type cladding layer; 4. N-type waveguide layer; 5. cascaded multi-active region; 6. P-type waveguide layer; 7. P-type cladding layer; 8. capping layer; 4a. N-type doped high refractive index layer; 4b. N-type doped low refractive index layer; 6a. P-type doped high refractive index layer; 6b. P-type doped low refractive index layer; 5e. confinement layer; 5a. high refractive index layer; 5b. active region; 5c. low refractive index layer; and 5d. tunnel junction.

5aN. N-region portion of the high refractive index layer of the confinement layer; 5aP. P-region portion of the high refractive index layer of the confinement layer; 5cP. P-region portion of the low refractive index layer of the confinement layer; 5cN. N-region portion of the low refractive index layer of the confinement layer; 5dP. p⁺-doped layer of the tunnel junction; and 5dN. n⁺-doped layer of the tunnel junction. 5b1. first active region; 5b2. second active region; 5b3. third active region, and so on; 5d1. first tunnel junction; 5d2. second tunnel junction, and so on; and the confinement layer consists of a first high refractive index layer 5a1, a first low refractive index layer 5c1, a second high refractive index layer 5a2, a second low refractive index layer 5c2, a third high refractive index layer 5a3, and the like.

9. fundamental mode near field; 911. first peak; 912. second peak; 913. third peak; 921. first trough; 922. second trough, and so on.

### DETAILED DESCRIPTION OF EMBODIMENTS

The technical solutions in the embodiments of the present application will be clearly and completely described below with reference to the accompanying drawings in the embodiments of the present application. It should be understood that the embodiments disclosed below are merely some embodiments of the disclosure, rather than all embodiments. Based on the embodiments provided herein, all other embodiments obtained by those of ordinary skill in the art without making creative efforts shall fall within the scope of the disclosure defined by the appended claims.

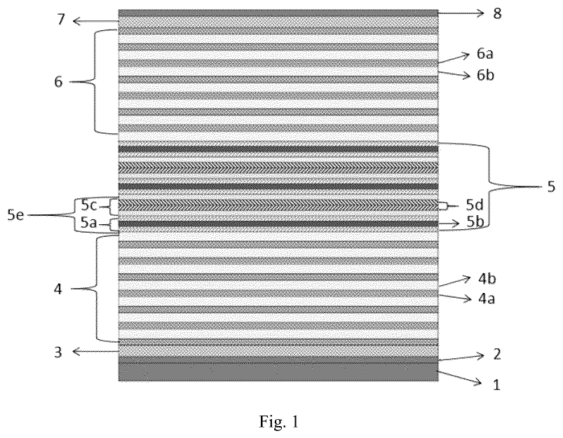

As illustrated in FIG. 1, a multi-active region cascaded Bragg reflection waveguide edge-emitting diode laser is provided, which includes a substrate 1, a buffer layer 2, an N-type cladding layer 3, an N-type waveguide layer 4, a cascaded multi-active region 5, a P-type waveguide layer 6, a P-type cladding layer 7 and a capping layer 8 arranged sequentially from bottom to top.

The substrate 1 is made of an N-type highly-doped III-V compound (containing elements from groups III and V from the periodic table), which can be GaAs, InP, GaSb or GaN.

The buffer layer 2 is grown on the substrate 1, and is an N-type highly doped material, which is usually the same as a material of the substrate, and is used to bury defects of the substrate 1 itself.

The N-type cladding layer 3 is grown on the buffer layer 2, and is an N-type doped material. A refractive index of the N-type cladding layer 3 is lower than that of the N-type waveguide layer 4, thereby limiting an expansion of a light field towards the substrate 1.

The N-type waveguide layer 4 is grown on the N-type cladding layer 3, and consists of m pairs of distributed Bragg reflectors (DBRs), formed by periodic and alternate growth of N-type doped high refractive index layers 4a and N-type doped low refractive index layers 4b, where a thickness of each period is T_{N}. A doping concentration of the N-type waveguide layer 4 gradually decreases from bottom to top.

The cascaded multi-active region 5 is grown on the N-type waveguide layer 4, and consists of multiple active regions 5b, tunnel junctions 5d and a confinement layer 5e. The confinement layer 5e consists of a plurality of high refractive index layers 5a and a plurality of low refractive index layers 5c. The plurality of high refractive index layers 5a can vary in composition and thickness. The plurality of low refractive index layers 5c can vary in composition and thickness. The active regions 5b are respectively located in the plurality of high refractive index layers 5a. The active regions 5b can independently be a single layer or multi-layer quantum well, quantum dot, quantum wire or other gain material. The tunnel junctions 5d are located in the plurality of low refractive index layers 5c.

The P-type waveguide layer 6 is grown on the cascaded multi-active region 5, and consists of n pairs of DBRs, formed by periodic and alternate growth of P-type doped high refractive index layers 6a and P-type doped high refractive index layers 6b, where a thickness of each period is T_{P}. The P-type doped high refractive index layers 6a and the 4a can be same in or different from the N-type doped high refractive index layers in composition and thickness. The P-type doped high refractive index layers 6b can be same in or different from the N-type doped low refractive index layers 4b in composition and thickness. A period number n of the P-type waveguide layer 6 is equal to or less than a period number m of the N-type waveguide layer 4. A doping concentration of the P-type waveguide layer 6 gradually increases from bottom to top.

The P-type cladding layer 7 is grown on the P-type waveguide layer 6 and is P-type doped. A refractive index of the P-type cladding layer 7 is lower than that of the P-type waveguide layer 6, thereby limiting the expansion of the light field towards the capping layer 8 which is heavily-doped. The refractive index of the P-type cladding layer 7 is less than or equal to the refractive index of the N-type cladding layer 3.

The capping layer 8 is grown on the P-type cladding layer 7, which is usually the same material as the substrate. The capping layer 8 is a P-type heavily-doped layer, which facilitates the ohmic contact.

In the multi-active region cascaded Bragg reflection waveguide edge-emitting diode laser provided by the embodiments of the present application, a component gradient layer can be introduced between each layer, so as to reduce barrier resistance.

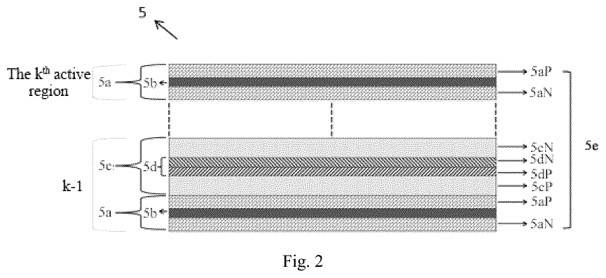

As illustrated in FIG. 2, a schematic diagram of the cascaded multi-active region 5 of the multi-active region cascaded Bragg reflection waveguide edge-emitting diode laser of the present disclosure is provided. The cascaded multi-active region 5 consists of k (k is equal to or larger than 2, and is a natural number) active regions 5b, k−1 tunnel junctions 5d and the confinement layer 5e. The confinement layer 5e consists of k high refractive index layers 5a and k−1 low refractive index layers 5c. The active regions 5b are respectively located in the high refractive index layers 5a. The tunnel junctions 5d are respectively located in the low refractive index layers 5c. Each of the tunnel junctions 5d consists of a p⁺-doped layer 5dP and an n⁺-doped layer 5dN.

The active regions 5b are respectively grown on N-region portions 5aN of the high refractive index layers of the confinement layer, which are undoped. Each of the active regions 5b has different doping types on both sides. The N-region portions 5aN adjacent to a bottom of each of the active regions 5b are N-type doped, and P-region portions 5aP of the high refractive index layers of the confinement layer grown on the active regions 5b are P-type doped. P-region portions 5cP of the low refractive index layers of the confinement layers are respectively grown on the P-region portions 5aP, which are P-type doped. The p⁺-doped layers 5dP of the tunnel junctions are respectively grown on the P-region portions 5cP. A P-type doping concentration of each of the p⁺-doped layers 5dP is usually higher than 10²⁰ cm⁻³. The n⁺-doped layers 5dN of the tunnel junctions are respectively grown on the p⁺-doped layers 5dP, and a P-type doping concentration of each of the n⁺-doped layers 5dN is usually higher than 10¹⁹ cm⁻³. N-region portions 5cN of the low refractive index layers of the confinement layer respectively grown on the n⁺-doped layers 5dN, and are N-type doped.

As mentioned above, it can be seen that the doping types of the materials on both sides of each of the active regions 5b are different. The material between each of the active regions 5b and a corresponding one of the p⁺-doped layers 5dP of an upper tunnel junction is P-type doped. The material between each of the active regions 5b and a corresponding one of the n⁺-doped layers 5dN of a nether tunnel junction is N-type doped. A doping concentration increases from each of the active regions 5b to both sides.

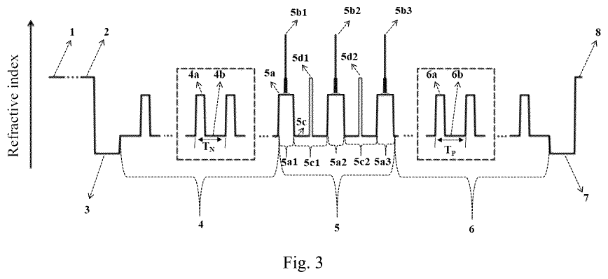

As illustrated in FIG. 3, refractive index distribution in individual layers of the multi-active region cascaded Bragg reflection waveguide edge-emitting diode laser is provided. The N-type waveguide layer 4 is formed by periodic and alternate growth of the N-type doped high refractive index layers 4a and the low refractive index layers 4, where the thickness of each period is T_{N}. The P-type waveguide layer 6 is formed by periodic and alternate growth of the P-type doped high refractive index layers 6a and the P-type doped high refractive index layers 6b, where the thickness of each period is T_{P}. The confinement layer 5e is formed by periodic and alternate growth of the high refractive index layers 5a and the low refractive index layers 5c, where a thickness of each period is T_{G}.

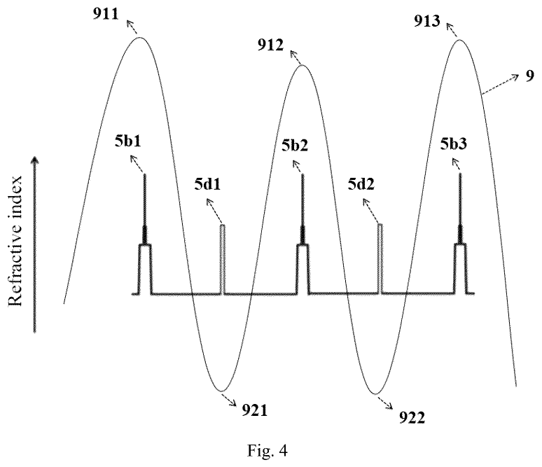

The compositions and thicknesses of the N-type waveguide layer 4, the P-type waveguide layer 6, the high refractive index layers 5a and the low refractive index layers 5c are adjusted, such that a fundamental mode near field 9 with periodic oscillation and near Gaussian distribution can be obtained. Positions of the active regions 5b in the high refractive index layers 5a of the confinement layer are respectively adjusted to allow the active regions 5b to be respectively located at peaks of the fundamental mode near field 9. Positions of the tunnel junctions 5d in the low refractive index layers 5c of the confinement layer are respectively adjusted to allow the tunnel junctions 5d to be respectively located at troughs of the fundamental mode near field 9. As illustrated in FIG. 4, the active regions 5b are configured to share the same waveguide.

The above technical solution disclosed in this application adopts a Bragg reflection waveguide to obtain the fundamental mode near field of periodic oscillation with the near Gaussian distribution, which allows the active regions and the tunnel junctions to be respectively and accurately located at the peaks and troughs of the fundamental mode near field, thereby achieving multi-active region cascading and reducing the light absorption loss of heavily-doped tunnel junction layers. The multiple active regions share a single large mode volume base mode and share the same waveguide layer, which can effectively reduce the voltage and is conducive to achieving high-power, high-beam quality laser output.

### Embodiment 1

Embodiment 1 of the disclosure provides a multi-active region cascaded Bragg reflection waveguide edge-emitting diode laser, which includes a substrate 1, a buffer layer 2, an N-type cladding layer 3, a N-type waveguide layer 4, a cascaded multi-active region 5, a P-type waveguide layer 6, a P-type cladding layer 7 and a capping layer 8 arranged sequentially from bottom to top.

The substrate 1 and the buffer layer 2 are N-type heavily doped GaAs material. The N-type cladding layer 3 is made of an Al_{0.45}Ga_{0.55}As material, and is N-type doped. The N-type waveguide layer 4 is made of 7 pairs of A_{10.35}Ga_{0.65}As/A_{10.2}Ga_{0.8}As periodic waveguides, and is N-type doped.

The cascaded multi-active region 5 includes: a first active region 5b1, a second active region 5b2, a third active region 5b3, a first tunnel junction 5d1, a second tunnel junction 5d2 and a confinement layer 5e. The confinement layer 5e includes: a first high refractive index layer 5a1, a first low refractive index layer 5c1, a second high refractive index layer 5a2, a second low refractive index layer 5c2, and a third high refractive index layer 5a3.

The first active region 5b1 and the second active region 5b2 are configured to realize tunneling cascade through the first tunnel junction 5d1. The second active region 5b2 and the third active region 5b3 are configured to realize tunneling cascade through the second tunnel junction 5d2.

The first active region 5b1 is located on the first high refractive index layer 5a1. The second active region 5b2 is located on the second high refractive index layer 5a2. The third active region 5b3 is located on the third high refractive index layer 5a3.

The first tunnel junction 5d1 is located on the first low refractive index layer 5c1. The second tunnel junction 5d2 is located on the second low refractive index layer 5c2.

The first active region 5b1, the second active region 5b2, and the third active region 5b3 all adopt an InGaAs double quantum well structure.

The first tunnel junction 5d1 and the second tunnel junction 5d2 are independently a p⁺- and n⁺-doped GaAs layer.

The first high refractive index layer 5a1, the second high refractive index layer 5a2, and the third high refractive index layer 5a3 all adopt an A_{10.2}Ga_{0.8}As material.

The first low refractive index layer 51 and the second low refractive index layer 5c2 both adopt an Al_{0.35}Ga_{0.65}As material.

The material between the active regions and the p⁺-doped layers 5dP is P-type doped. The material between the active regions and the n⁺-doped layers 5dN is N-type doped. A doping concentration increases from each of the active regions to both sides.

The P-type waveguide layer 6 is made of 7 pairs of Al_{0.35}Ga_{0.65}As/Al_{0.2}Ga_{0.8}As periodic waveguides. The P-type cladding layer 7 is made of an Al_{0.45}Ga_{0.55}As material, and a thickness of the P-type cladding layer 7 is greater than that of the N-type cladding layer 3. The capping layer 8 is made of a heavily-doped GaAs material.

The components and thicknesses of the N-type waveguide layer 4, the P-type waveguide layer 6, the first high refractive index layer 5a1, the first low refractive index layer 5c1, the second high refractive index layer 5a2, the second low refractive index layer 5c2, and the third high refractive index layer 5a3 are adjusted, such that a fundamental mode near field 9 of periodic oscillation with a near Gaussian distribution can be obtained. Positions of the first active region 5b1, the second active region 5b2, and the third active region 5b3 in the first high refractive index layer 5a1, the second high refractive index layer 5a2, and the third high refractive index layer 5a3 of the confinement layer are respectively adjusted to allow the first active region 5b1 to be located at a first peak 911 of the fundamental mode near field 9, the second active region 5b2 to be located at a second peak 912 of the fundamental mode near field 9, and the third active region 5b3 to be located at a third peak 913 of the fundamental mode near field 9.

Positions of the first tunnel junction 5d1 and the second tunnel junction 5d2 in the first low refractive index layer 5c1 and the second low refractive index 5c2 of the confinement layer are adjusted to allow the first tunnel junction 5d1 to be located at a first trough 921 of the fundamental mode near field 9, and the second tunnel junction 5d2 to be located at a second trough 922 of the fundamental mode near field 9.

Moreover, the first active region 5b1, the second active region 5b2, and the third active region 5b3 are all located at the same waveguide.

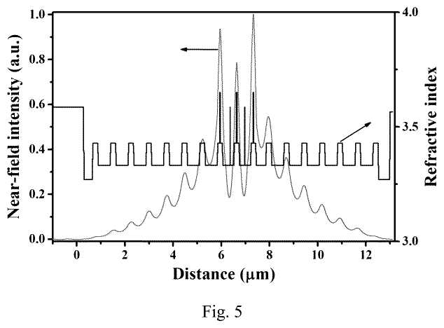

As illustrated in FIG. 5, refractive index distribution and fundamental mode near-field intensity distribution of the multi-active region cascaded Bragg reflection waveguide edge-emitting diode laser with a wavelength of 905 nm according to Embodiment 1 of the present disclosure is obtained. The fundamental mode near field of the laser of the present disclosure is formed by periodic oscillating peaks, with an envelope close to Gaussian distribution. A vertical direction optical mode volume of the fundamental mode near field is larger than 10 μm, which can achieve stable single-mode operation. Three of the active regions are respectively located at the peaks of the fundamental mode near field, which can obtain a high light confinement factor. Two of the tunnel junctions are respectively located at the troughs of the fundamental mode near field, which can effectively reduce the light absorption loss in the heavily-doped region.

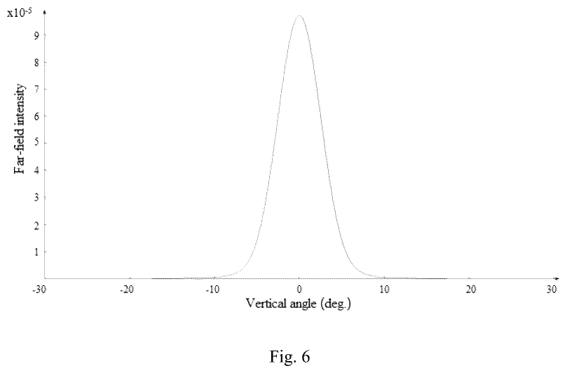

As illustrated in FIG. 6, far-field intensity distribution of the multi-active region cascaded Bragg reflection waveguide edge-emitting diode laser is obtained in Embodiment 1. It can be seen that a narrow single-beam laser in a vertical direction is output by the laser. A vertical divergence angle of a full width at half maximum is about 7°, which is much lower than divergence angles of the commercially-available devices.

### Embodiment 2

The difference between Embodiment 2 and Embodiment 1 of the disclosure is that: the N-type waveguide layer adopts 7 pairs of Al_{0.35}Ga_{0.65}As/Al_{0.2}Ga_{0.8}As periodic waveguides, while the P-type waveguide layer adopts 1 pair of Al_{0.35}Ga_{0.65}As/Al_{0.2}Ga_{0.8}As periodic waveguides (high and low refractive index layers are different from an N-type waveguide layer in thickness). A refractive index of a P-type cladding layer is lower than that of an N-type cladding layer.

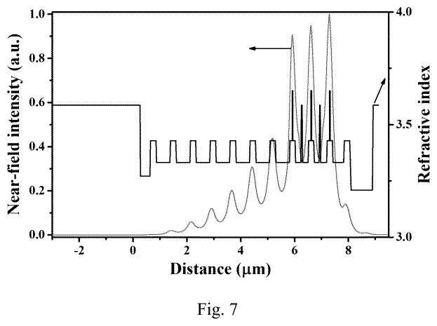

As illustrated in FIG. 7, refractive index distribution and fundamental mode near-field intensity distribution of the multi-active region cascaded Bragg reflection waveguide edge-emitting diode laser with a wavelength of 905 nm according to Embodiment 2 of the present disclosure is obtained. The thickness of a P-type doped region is reduced, such that the light absorption loss and the device resistance can be reduced, which is conducive to improving a conversion efficiency of the laser and reducing the difficulty of preparing surface gratings to achieve wavelength locking.

In the multi-active region cascaded Bragg reflection waveguide edge-emitting diode laser provided herein, the material and thickness of individual layers in the Bragg reflection waveguide and the cascaded multi-active region are controlled to allow light to be transmitted in the high refractive index layers in the Bragg reflection waveguide but to be gradually attenuated in the low refractive index layers, thereby forming a periodic-oscillating Gaussian-like near-field distribution. An amplitude difference of oscillating peaks near the active regions is increased to allow the active region and the tunnel junction to be located at the peak and trough of the fundamental mode near field, respectively, which can effectively improve the optical confinement factor and reduce the absorption loss of the tunnel junctions, thereby generating a high-power, low-beam divergence laser output. In addition, since the multiple active regions share a single vertical waveguide mode, output wavelength locking and spectral narrowing of the multiple active regions can be achieved simultaneously through integrating a grating.

In the technical solutions of the disclosure disclosed above, a Bragg reflection waveguide structure is adopted to achieve a light field with Gaussian-like distribution with large-amplitude periodic oscillation. In this way, the multiple active regions can be introduced at peaks of a central light field, and the tunnel junctions can be introduced at troughs of a light field near the active regions, so as to reduce the light absorption loss and achieve high-power laser output. The laser also has characteristics of a large laser cavity and a strong mode selection, which can achieve stable single-mode operation with a large optical mode volume, effectively improving the cavity surface catastrophic damage power and beam quality. Meanwhile, a vertical divergence angle can be compressed from more than 30° of traditional devices to less than 10°, which is more conducive to device collimation and application. In addition, the multi-active regions of the laser share the same waveguide mode. Through buried growth or surface etching gratings, wavelength locking and spectral narrowing of the multi-active regions can be achieved simultaneously, making it feasible for lidar systems to use narrow-band filters to suppress background light noise, which is of great significance. In general, the laser can achieve laser output with high pulse power and low beam divergence, and has a promising application prospect.

It should be noted that in this application, relational terms such as “first” and “second” are only used to distinguish one entity or operation from another entity or operation, and do not necessarily require or imply any actual relationship or order between these entities or operations. Furthermore, terms “comprise”, “include”, or any other variations thereof are intended to cover a non-exclusive inclusion such that elements inherent in a process, method, article, or apparatus are included. Without further limitation, an element defined by the statement “comprises a . . . ” does not exclude the presence of additional identical elements in a process, method, article, or apparatus that includes the mentioned element. In addition, the part of the above technical solutions provided by the embodiments of the present application that are consistent with implementation principles of the corresponding technical solutions in the prior art have not been described in detail herein to simplify the description.

The detailed description of the embodiments disclosed herein is intended to enable those skilled in the art to implement or use the present application. Though the disclosure has been described in detail above, various modifications, changes and replacements can still be made by those skilled in the art. It should be understood that those modifications, changes and replacements made without departing from the spirit or scope of the application shall fall within the scope of the disclosure defined by the appended claims.

What is claimed is:

1. A multi-active region cascaded Bragg reflection waveguide edge-emitting diode laser, comprising:
a substrate;
a buffer layer;
an N-type cladding layer;
an N-type waveguide layer;
a cascaded multi-active region;
a P-type waveguide layer;
a P-type cladding layer; and
a capping layer;
wherein the substrate, the buffer layer, the N-type cladding layer, the N-type waveguide layer, the cascaded multi-active region, the P-type waveguide layer, the P-type cladding layer and the capping layer are sequentially arranged from bottom to top; the N-type waveguide layer is a Bragg reflection waveguide formed by periodic and alternate growth of a plurality of first refractive index layers and a plurality of second refractive index layers, and the P-type waveguide layer is a Bragg reflection waveguide formed by periodic and alternate growth of a plurality of third refractive index layers and a plurality of fourth refractive index layers; a refractive index of the plurality of first refractive index layers is larger than that of the plurality of second refractive index layers; a refractive index of the plurality of third refractive index layers is larger than that of the plurality of fourth refractive index layers; the cascaded multi-active region comprises a plurality of active regions, a plurality of tunnel junctions and a confinement layer; the plurality of active regions and the plurality of tunnel junctions are located in the confinement layer; each of the plurality of tunnel junctions is located between two adjacent active regions of the plurality of active regions; the plurality of active regions are respectively located at peaks of a fundamental mode near field; the plurality of tunnel junctions are respectively located at troughs of the fundamental mode near field; and the plurality of active regions are configured to share the same waveguide.

2. The multi-active region cascaded Bragg reflection waveguide edge-emitting diode laser of claim 1, wherein the confinement layer comprises:
a plurality of fifth refractive index layers; and
a plurality of sixth refractive index layers;
wherein a refractive index of the plurality of fifth refractive index layers is larger than that of the plurality of sixth refractive index layers; the plurality of fifth refractive index layers and the plurality of sixth refractive index layers are configured to grow alternately; the plurality of active regions are respectively inserted in the plurality of fifth refractive index layers; and the plurality of tunnel junctions are respectively inserted in the plurality of sixth refractive index layers.

3. The multi-active region cascaded Bragg reflection waveguide edge-emitting diode laser of claim 2, wherein the plurality of fifth refractive index layers vary in composition and thickness; and the plurality of sixth refractive index layers vary in composition and thickness.

4. The multi-active region cascaded Bragg reflection waveguide edge-emitting diode laser of claim 3, wherein the number k of the plurality of active regions is equal to or larger than 2; and the number of the plurality of tunnel junctions is k−1, wherein k is a natural number.

5. The multi-active region cascaded Bragg reflection waveguide edge-emitting diode laser of claim 4, wherein the plurality of first refractive index layers are different from the plurality of third refractive index layers in composition and thickness; the plurality of second refractive index layers are different from the plurality of fourth refractive index layers in composition and thickness; and a period number of the plurality of third refractive index layers and the fourth refractive index layers is less than or equal to a period number of the plurality of first refractive index layers and the plurality of second refractive index layers.

6. The multi-active region cascaded Bragg reflection waveguide edge-emitting diode laser of claim 5, wherein a refractive index of the P-type cladding layer is lower than a refractive index of the N-type cladding layer.

7. The multi-active region cascaded Bragg reflection waveguide edge-emitting diode laser of claim 1, wherein each of the plurality of tunnel junctions comprises a first doped material and a second doped material; a conductivity type of the first doped material is opposite to that of the second doped material; and for each of the plurality of tunnel junctions, a conductivity type of a material between the first doped material and an adjacent active region thereof is different from that of a material between the second doped material and an adjacent active region thereof.

8. The multi-active region cascaded Bragg reflection waveguide edge-emitting diode laser of claim 1, wherein the plurality of active regions are independently a single-layer or multi-layer quantum well, quantum dot or quantum wire.

9. The multi-active region cascaded Bragg reflection waveguide edge-emitting diode laser of claim 1, wherein the substrate is GaAs, InP, GaSb or GaN.
